(19) United States
(12) Patent Application Publication
(10) Pub. No.: US 2009/0256214 A1
(43) Pub. Date: Oct. 15, 2009

(54) Semiconductor device and associated methods

(76) Inventors: Min-Chul Sun, Hwaseong-si (KR); Dong-Suk Shin, Yongin-si (KR); Jung-Deog Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/385,574

(22) Filed: Apr. 13, 2009

(30) Foreign Application Priority Data
Apr. 14, 2008 (KR) 10-2008-0034273

(51) Int. Cl. H01L 29/78

(52) U.S. Cl. 257/411; 257/E29.255

(57) ABSTRACT

A semiconductor device and process of fabricating the same, the semiconductor device including a semiconductor substrate, a gate insulating layer on the semiconductor substrate, a gate electrode having sidewalls, on the gate insulating layer, first spacers on the sidewalls of the gate electrode, a source/drain region in the semiconductor substrate, aligned with the sidewalls, a silicide layer on the gate electrode, a silicide layer on the source/drain region, and second spacers covering the first spacers and end parts of a surface of the silicide layer on the source drain region.

### BACKGROUND

1. Technical Field

Embodiments relate to a semiconductor device and associated methods.

2. Description of the Related Art

A semiconductor device may include individual elements, e.g., transistors, capacitors, and the like, and interconnection lines for connecting the individual elements. The semiconductor device may also include contacts for connections between individual elements, between an individual element and an interconnection line, and between interconnection lines, respectively.

With the recent trend of high performance of semiconductor devices, the size of gate electrodes of the semiconductor device has been reduced below submicron (sub-μm) levels, achieving a high-degree integration of the devices. Accordingly, not only the size of the elements, but also the size of interconnection lines and contacts have been abruptly reduced. Margins in a region in which the interconnection lines and the contacts may be formed have also been reduced. This margin reduction, due to the increase of the degree of integration, may cause an electrical short between the interconnection line and the contact.

As the degree of integration of the semiconductor device is increased, there is a need for a semiconductor device and a method of fabricating the same, which may improve the performance of the semiconductor device with contact forming margins sufficiently secured.

### SUMMARY

Embodiments are therefore directed to a semiconductor device and associated methods, which substantially overcome one or more of the problems due to the limitations and disadvantages of the related art.

It is therefore a feature of an embodiment to provide a semiconductor device in which an electric short between adjacent conductive elements is prevented.

At least one of the above and other features and advantages may be realized by providing a semiconductor device, including a semiconductor substrate, a gate insulating layer on the semiconductor substrate, a gate electrode having sidewalls, on the gate insulating layer, first spacers on the sidewalls of the gate electrode, a source/drain region in the semiconductor substrate, aligned with the sidewalls, a silicide layer on the gate electrode, a silicide layer on the source/drain region having a surface with an end part, and second spacers covering the first spacers and the end parts of the surface of the silicide layer on the source drain region.

The semiconductor device may further include an etch stop layer overlying at least part of the semiconductor substrate, the etch stop layer having a contact hole exposing the second spacer and at least a part of the silicide layer on the source/drain region.

The contact hole may further expose at least a part of the silicide layer on the gate electrode.

The second spacer may include a material having a high etch selectivity with respect to the etch stop layer.

The etch stop layer may include a silicon nitride layer.

The second spacer may include silicon oxide or a high dielectric constant (high-k) material.

The semiconductor device may further include L-type spacers between the gate electrode and the first spacers, wherein the L-type spacers cover the sidewalls of the gate electrode and overlie at least a part of the semiconductor substrate.

The source/drain region may include a low-density source/drain region under the L-type spacer.

The semiconductor substrate may include an isolation region defining an active region.

The isolation region may be in contact with a lower part of a gate electrode and the source/drain region.

At least one of the above and other features and advantages may also be realized by providing a method of fabricating a semiconductor device, including providing a semiconductor substrate, forming a gate insulating layer on the semiconductor substrate, forming a gate electrode having sidewalls on the gate insulating layer, forming first spacers on the sidewalls of the gate electrode, forming a source/drain region in the semiconductor substrate, the source/drain region extending under the first spacers to align with the sidewalls of the gate electrode, forming silicide layers on the gate electrode and the source/drain region, and forming second spacers covering the first spacers and an end part of the surface the silicide layer on the source/drain region.

The step of providing the semiconductor substrate may include forming an isolation region defining an active region in the semiconductor substrate.

The source/drain region may be in contact with the isolation region.

The step of forming the second spacers may include conformally forming a second spacer insulating layer on a surface of the semiconductor substrate having the silicide layers, and performing an anisotropic etching process on the second spacer insulating layer to form the second spacers.

The method may further include forming an etch stop layer on the semiconductor substrate having the second spacers, forming an interlayer insulation layer on the etch stop layer, and forming a contact hole exposing the second spacers and at least a part of the silicide layer on the source/drain region by etching the interlayer insulating layer and the etch stop layer.

The second contact hole may further expose at least a part of the silicide layer on the gate electrode.

The etch stop layer may include a material having a high etch selectivity with respect to the second spacers.

The etch stop layer may include a silicon nitride layer.

The second spacer may include silicon oxide or a high dielectric constant (high-k) material.

The method may further include forming L-type spacers covering sidewalls of the gate electrode and overlying at least a part of the semiconductor substrate, before forming the first spacers.

The step of forming the source/drain region may include forming a low-density source/drain region extending under lower parts of the L-type spacers.

### BRIEF DESCRIPTION OF THE DRAWINGS

The above and other features and advantages will become more apparent to those of ordinary skill in the art by describing in detail exemplary embodiments thereof with reference to the attached drawings, in which:

FIGS. 1 and 2 illustrate sectional views of a semiconductor device according to an embodiment;

FIG. 3 illustrates a flowchart briefly showing a method of fabricating a semiconductor device according to an embodiment;

FIGS. 4A to 4G illustrate sectional views of a method of fabricating a semiconductor device according to an embodiment; and

FIGS. 5A to 5H illustrate sectional views of a method of fabricating a semiconductor device according to another embodiment.

### DETAILED DESCRIPTION

Korean Patent Application No. 10-2008-0034273, filed on Apr. 14, 2008, in the Korean Intellectual Property Office, and entitled: “Semiconductor Device and Method of Fabricating the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B, and C together, whereas the expression “either A, B, or C” means one of A alone, B alone, and C alone, and does not mean any of both A and B together; both A and C together; both B and C together; and all three of A, B, and C together.

As used herein, the terms “a” and “an” are open terms that may be used in conjunction with singular items or with plural items. For example, the term “a high dielectric material” may represent a single compound, e.g., silicon oxide, or multiple compounds in combination, e.g., silicon oxide mixed with hafnium oxide.

In the entire description of the embodiments, the same drawing reference numerals are used for the same elements across various figures. Also, the term “coupled to” means that an element is electrically connected to another element.

Spatially relative wordings “below”, “beneath”, “lower”, “above”, “upper”, and so forth, as illustrated in the drawings, may be used to facilitate the description of relationships between an element or constituent elements and another element or other constituent element. The spatially relative wordings should be understood as wordings that include different directions of the element in use or operation in addition to the direction illustrated in the drawings. In the entire description of the present invention, the same drawing reference numerals are used for the same elements across various figures.

In the following description, embodiments will be described with reference to the drawing FIGS., which are ideal schematic views. The form of exemplary views may be modified due to the manufacturing techniques and/or allowable errors. Accordingly, the embodiments are not limited to their specified form as illustrated, but include changes in form being produced according to manufacturing processes. Accordingly, areas exemplified in the drawings have rough properties, and the shapes of areas in the drawings are to exemplify specified forms of areas of elements, but do not limit the scope of the present invention.

Hereinafter, a semiconductor device and a method of fabricating the same according to the embodiments will be described in detail with reference to the accompanying drawings. The semiconductor device in the description may include a high-integration semiconductor memory device, e.g., a DRAM, an SRAM, a flash memory, and the like, a MEMS (Micro Electro Mechanical Systems) device, an optoelectronic device, or a processor, e.g., a CPU, a DSP, and the like. Also, the semiconductor device may include semiconductor devices of the same kind, or may include a chip data processing device such as an SOC (System On Chip) including semiconductor devices of various kinds required to provide one complete function.

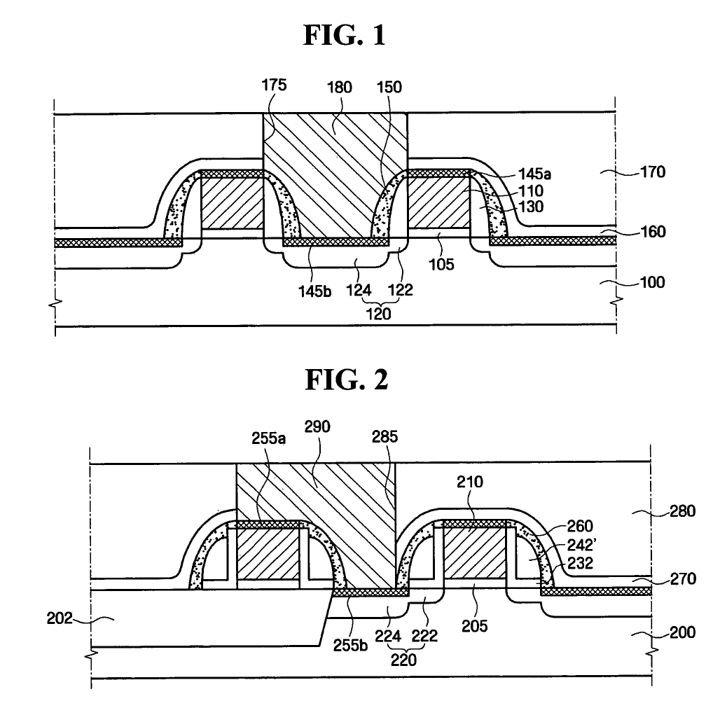

First, with reference to FIG. 1, a semiconductor device according to an embodiment will be described in detail. FIG. 1 illustrates a sectional view of a semiconductor device according to an embodiment.

As illustrated in FIG. 1, on a semiconductor substrate 100, a plurality of gate patterns may be positioned at specified intervals. The gate patterns positioned on the semiconductor substrate 100 may have a structure in which gate insulating layers 105 and gate electrodes 110 are laminated. First spacers 130 may be formed on sides of the gate patterns.

Source/drain regions 120, into which impurities may be ion-injected, may be formed in the semiconductor substrate 100 on the sides of the gate electrode 110. The source/drain region 120 may include a low-density source/drain region 122 aligned with a sidewall of the gate electrode 110, and a high-density source/drain region 124 aligned with an edge of the first spacer 130. Also, silicide layers 145a and 145b, which may reduce contact resistance when a contact is formed thereon, may be formed on an upper surface of the gate electrode 110 and on a surface of the high-density source/drain region 124, respectively.

On the first spacer 130, a second spacer 150 may extend from a sidewall of the silicide layer 145a on the upper surface of the gate electrode 110 to the silicide layer 145b on the surface of the high-density source/drain region 124. That is, the second spacer 150 may cover the surface of the first spacer 130 and an end part of the surface of the silicide layer 145b on the high-density source/drain region 124.

On the above-described structures, an etch stop layer 160 and an interlayer insulating layer 170 may be formed. A contact hole 175 exposing at least a part of the silicide layer 145b on the high-density source/drain region 124 may be formed. The etch stop layer 160 may be conformally formed in contact with surfaces of the semiconductor substrate 100, the silicide layers 145a and 145b, and the second spacers 150.

The etch stop layer 160 may include, e.g., an insulating material different from the second spacer 150. Accordingly, when the contact hole 175 is formed, damage to the first spacers 130 due to an over-etching of the etch stop layer 160 may be prevented. Damage to the surface of the end part of the silicide layer 145b on the high-density source/drain region 124 may also be prevented.

The contact hole 175 may expose surfaces of the second spacers 150 on the sides of the gate electrode 110, and at least a part of the silicide layer 145b on the high-density source/drain region 124. Since damage to the silicide layers 145a and 145b may be prevented by the second spacer 150, an electrical short of the contact 180 electrically connected to the source/drain region 120 and/or a leakage current may be prevented.

Hereinafter, with reference to FIG. 2, a semiconductor device according to another embodiment will be described. Referring to FIG. 2, a semiconductor substrate 200 may be divided into a field region and an active region by an isolation region 202, and a plurality of gate patterns may be positioned on the active region.

The plurality of gate patterns on the semiconductor substrate 200 may have a structure in which gate insulating layers 205 and gate electrodes 210 are laminated. L-type spacers 232, which may extend from sidewalls of the gate pattern to overlie parts of the semiconductor substrate 200, may be positioned on the sides of the gate patterns. The L-type spacers 232 may be conformally formed with a uniform thickness on sidewalls of the gate pattern and the surface of the semiconductor substrate 200. First spacers 242′ may be positioned on the L-type spacers 232. The first spacer 242′ formed on the L-type spacer 232 may have an upper part having a width narrower than the width of a lower part. Also, the first spacers 242′ may be removed depending on a process.

Source/drain regions 220, into which impurities are ion-injected, may be formed in the active region at the sides of the gate pattern, i.e. in the semiconductor substrate 200. The source/drain region 220 may include a low-density source/drain region 222 aligned with a sidewall of the gate electrode 210, and a high-density source/drain region 224 aligned with an edge of the L-type spacer 232. Also, silicide layers 255a and 255b, which may reduce contact resistance when a contact is formed thereon, may be formed on an upper surface of the gate electrode 210, and on a surface of the high-density source/drain region 224, respectively.

On the sides of the gate pattern, second spacers 260 may surround the L-type spacers 232 and the first spacers 242′. That is, the second spacers 260 may extend from the sidewalls of the silicide layer 255a on the upper part of the gate electrode 210 to end parts of the surface of the silicide layer 255b on the high-density source/drain region 224. Accordingly, the surface of the first spacers 242′ and the end parts of the surface of the silicide layer 255b on the high-density source/drain region 224 may be protected by the second spacers 260. If the first spacers 242′ are removed, the second spacers 260 may cover a part or all parts of the L-type spacers 232.

On the above-described structures, an etch stop layer 270 and an interlayer insulating layer 280 may be formed. A common contact hole 285 exposing the silicide layers 245a and 245b may be formed in the etch stop layer 270 and the interlayer insulating layer 280.

As the degree of integration of the semiconductor device is increased, the common contact hole 285, may form a contact and an interconnection line together in order to secure a process margin when the contact and the interconnection line for an electrical connection between the gate electrode 210 and the source/drain region 220 are formed. That is, the common contact hole 285 may expose parts of both silicide layers 255a and 255b on the gate electrode 210 and the high-density source/drain region 224.

The etch stop layer 270 may be conformally formed in contact with surfaces of the semiconductor substrate 200, the silicide layers 255a and 255b, and the second spacers 260. The etch stop layer 270 may include, e.g., an insulating material different from the second spacers 260. Thus, damage to the L-type spacer 232, the first spacer 242′, and the silicide layer 255b may be prevented when the common contact hole 285 is formed. Accordingly, an electrical short of the common contact 290 electrically connected to the gate electrode 210 and the source/drain region 220 and/or a leakage current may be prevented.

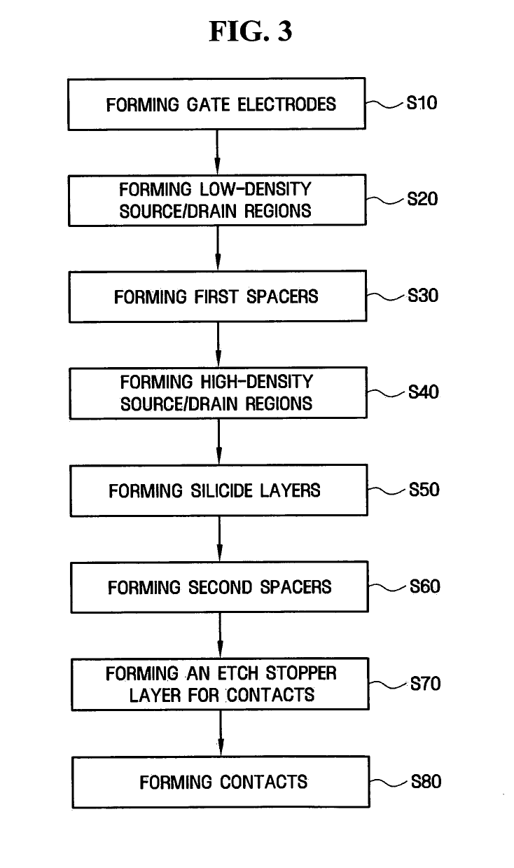

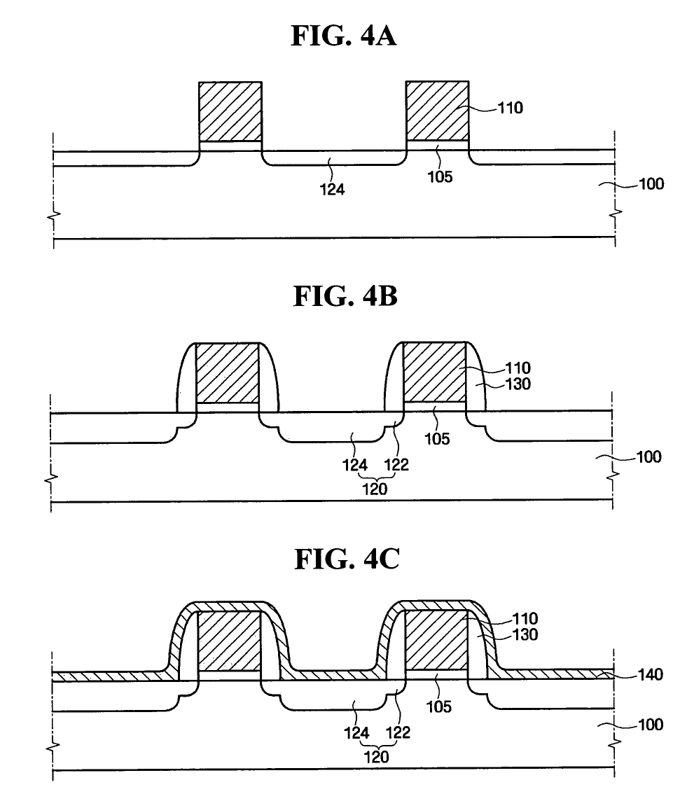

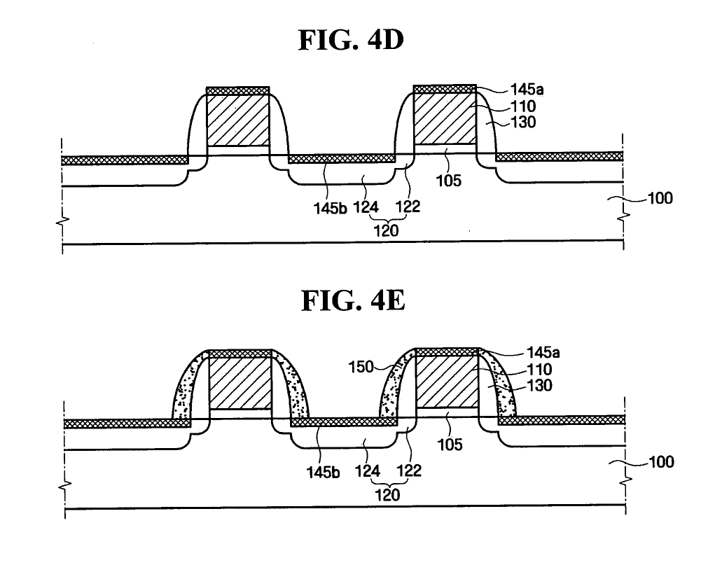

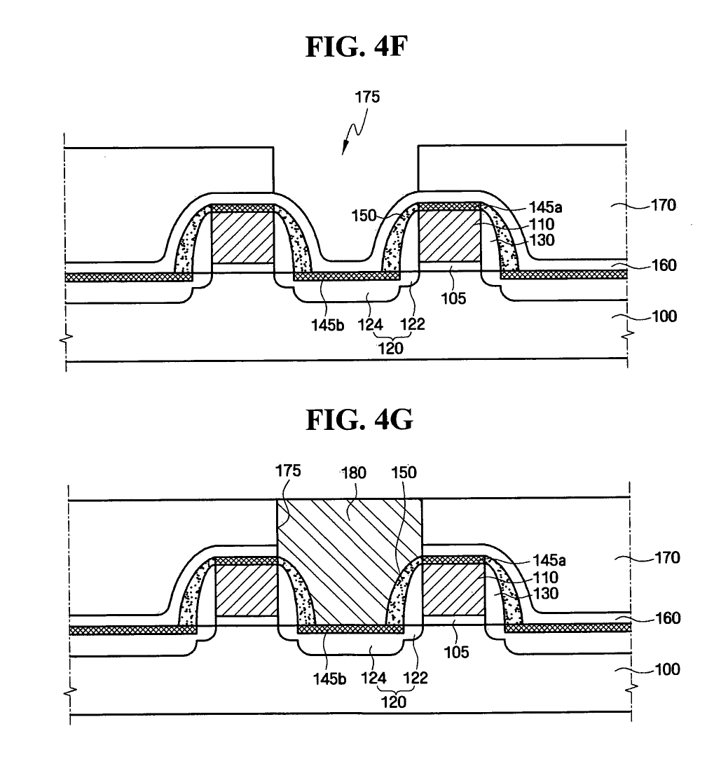

Hereinafter, a method of fabricating a semiconductor device according to an embodiment will be described in detail. FIG. 3 illustrates a flowchart briefly showing a method of fabricating a semiconductor device according to an embodiment. FIGS. 4A to 4G illustrate sectional views explaining a method of fabricating a semiconductor device according to an embodiment.

First, referring to FIGS. 3 and 4A, a gate electrode 110 may be formed on a semiconductor substrate 100 (S10). Specifically, on specified regions of the semiconductor substrate 100, gate insulating layers 105 and gate electrodes 110 may be formed in that order. The semiconductor substrate 100 may be, e.g., a substrate including at least one of Si, Ge, SiGe, GaP, GaAs, SiC, SiGeC, InAs, and InP, or an SOI (Silicon On Insulator) substrate.

The gate insulating layer 105 may include, e.g., an oxide layer, a silicon oxide layer formed by thermally oxidizing the semiconductor substrate 100, a layer of SiOₓN_{y}, GeOₓN_{y}, GeSiOₓ, silk, polyimide, a high dielectric constant (high-k) material, a combination thereof, or a laminated layer where the above-described materials are laminated. The high-k material may include, e.g., Al₂O₃, Ta₂O₅, HfO₂, ZrO₂, hafnium silicate, zirconium silicate, or the like.

The gate electrode 110 may be formed as a conductive layer including, e.g., polysilicon (poly-Si) doped with impurities, tungsten, Si—Ge, Ge, or a laminated layer thereof The polysilicon may be doped with, e.g., n-type or p-type impurities, and if impurities of the same conduction type as a transistor to be formed are doped, the characteristic of the transistor may be improved.

After the gate electrodes 110 are formed on the semiconductor substrate 100, low-density source/drain regions 122 may be formed in the semiconductor substrate 110 at the sides of the gate electrodes 110 (S20). The low-density source/drain regions 122 may be formed by an ion injection of impurities onto the semiconductor substrate 110 at the sides of the gate electrodes 110, using the gate electrodes 110 as an ion-injection mask. For the ion injection, n-type impurities, e.g., P or As, may be injected into an NMOS active region, while p-type impurities, e.g., B, may be injected into a PMOS active region.

A halo ion implantation for injecting impurities for forming the low-density source/drain region 130 and opposite type impurities may be performed in order to prevent an undesirable punch-through phenomenon due to the shortening of a channel length. That is, p-type impurities, e.g., B, may be injected into an NMOS active region, while n-type impurities, e.g., P or As, may be injected into a PMOS active region.

Next, referring to FIGS. 3 and 4B, first spacers 130 may be formed on sides of the gate electrode 110 (S30). The first spacers 130 may insulate sidewalls of the gate electrode 110, and may serve as an ion injection mask for forming the high-density source/drain regions 124 in the semiconductor substrate 100. Specifically, a first spacer insulating layer may be conformally formed on the surface of the semiconductor substrate 100 having the gate electrodes 110. The first spacer insulating layer may include, e.g., a silicon oxide layer formed by, e.g., a chemical vapor deposition (CVD), or a silicon oxide layer formed by, e.g., thermally oxidizing side surfaces of the gate electrode 110. Damage to the gate electrode 110 due to etching of may be prevented by the first spacer insulating layer.

An anisotropic etching process may then be performed with respect to the first spacer insulating layer, forming the first spacers 130 on sides of the gate electrodes 110. Then, the high-density source/drain regions 124 may be formed by injecting impurities using the first spacers 130 as the ion injection mask, completing formation of the source/drain regions 120 (S40). Here, n-type impurities, e.g., P or As, may be injected into an NMOS active region, while p-type impurities, e.g., B, may be injected into a PMOS active region. In this case, the density of the impurities and the ion injection energy may be greater than those for forming the low-density source/drain region 122.

As illustrated in FIG. 4C, a metal layer 140 for forming silicide layers may be formed on surfaces of the semiconductor substrate 100, the gate electrodes 110, and the first spacers 130. The metal layer 140 may be formed by depositing, e.g., titanium (Ti), tungsten (W), cobalt (Co), or nickel (Ni), on the surfaces.

By performing a thermal process on the whole surface of the resultant structure, the metal material and silicon atoms may react with each other to form silicide layers. The thermal process for forming silicide layers may be performed using, e.g., a rapid thermal processing (RTP) device, a furnace, or a sputtering device.

Then, by removing the non-reacted metal layer through a cleaning process, as illustrated in FIGS. 3 and 4D, silicide layers 145a and 145b may be formed on the gate electrode 110 and the source/drain region 120, respectively (S50). Specifically, the silicide layer 145b on the source/drain region 120 may be formed only on the high-density source/drain region 124.

While the silicide layers 145a and 145b may be formed after the first spacers 130 are formed on the sides of the gate electrode 110, a plurality of cleaning processes, e.g., pre/post cleaning processes for the surfaces of the high-density source/drain regions 124, cleaning processes before/after the silicide layers 145a and 145b are formed, and the like, may be performed. Accordingly, at least a part of the first spacers 130 on sides of the gate electrode 110 may be removed.

Next, referring to FIGS. 3 and 4E, second spacers 150 may be formed on the first spacers 130 on sides of the gate electrode 110 (S60). The second spacers 150 may extend from the upper parts of the gate electrode 110 to the semiconductor substrate 100. That is, the second spacers 150 may cover the sidewalls of the silicide layer 145a on the gate electrode 110, the surface of the first spacers 130, and the end parts of the surface of the silicide layer 145b on the high-density source/drain region 124.

The second spacers 150 may be formed by, e.g., conformally depositing an second spacer insulating layer on surfaces of the semiconductor substrate having the silicide layers, and then performing an anisotropic etching of the second spacer insulating layer. Here, the second spacer insulating layer may include a material having an etch selectivity with respect to an etch stop layer (See 160 in FIG. 4F) formed in a subsequent process. For example, when the etch stop layer includes a silicon nitride layer, the second spacers 150 may include a high-k material, e.g., silicon oxide (SiO₂), hafnium oxide (HfOₓ), zirconium oxide (ZrOₓ), hafnium oxynitride (HfOₓN_{y}), zirconium oxynitride (ZrOₓN_{y}), hafnium aluminum oxide (HfAlOₓ), zirconium aluminum oxide (ZrAlOₓ), hafnium silicon oxide (HfSiOₓ), zirconium silicon oxide (ZrSiOₓ), hafnium silicon oxynitride (HfSiOₓN_{y}), and zirconium silicon oxynitride (ZrSiOₓN_{y}).

Next, referring to FIGS. 3 and 4F, the etch stop layer 160 may be conformally formed on the semiconductor substrate 100 (S70). That is, the etch stop layer 160 may be conformally formed on the surfaces of the silicide layers 145a and 145b and the second spacers 150. The etch stop layer 160 may include, e.g., a silicon nitride layer, formed by, e.g., chemical vapor deposition (CVD).

Then, on the etch stop layer 160, an interlayer insulating layer 170 may be formed with a sufficient thickness. The interlayer insulating layer 170 may include, e.g., a high-density plasma oxide layer or a CVD oxide layer. With respect to the upper surface of the interlayer insulating layer 170, a planarization process may be performed by, e.g., chemical mechanical polishing (CMP).

Thereafter, a mask pattern (not illustrated) defining a contact hole 175 may be formed on the interlayer insulating layer 170. Then the contact hole 175 exposing the upper surface of the etch stop layer 160 may be formed by etching the interlayer insulating layer 170 using the mask pattern as an etching mask.

Then, an over-etching may be performed with respect to the etch stop layer 160 exposed by the contact hole 175, exposing the surface of the silicide layer 145b on the source/drain region 120. During the etching of the etch stop layer 160 through an over-etching process, the etch selectivity of the second spacer 150 with respect to the etch stop layer 160 may be high, and thus damage to the first spacer 130 may be prevented. Also, damage to the end part of the surface of the silicide layer 145b may be prevented. Accordingly, an electrical short between the contact 180 that fills the contact hole 175 and the gate electrode 110 may be prevented. An undesirable leakage current occurring at the end part of the silicide layer 145b may also be prevented. As illustrated in FIGS. 3 and 4G, by filling the contact hole 175 with a conductive material, the contact 180 electrically connecting to the source/drain region 120 may be completed (S80).

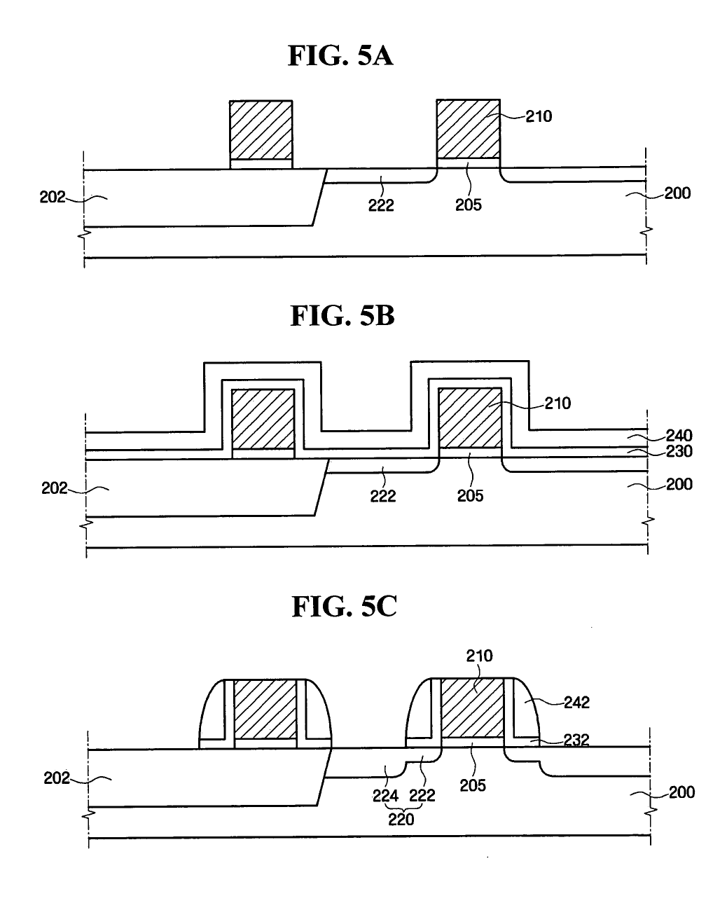

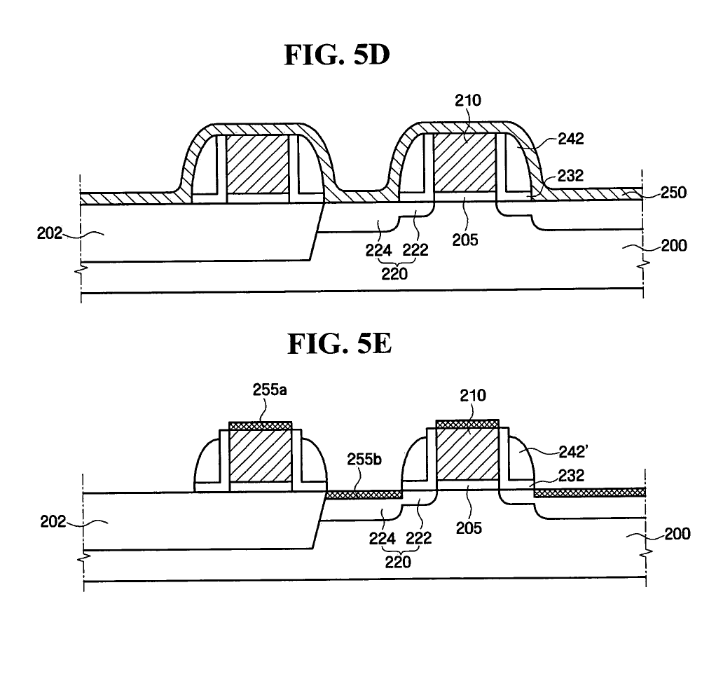

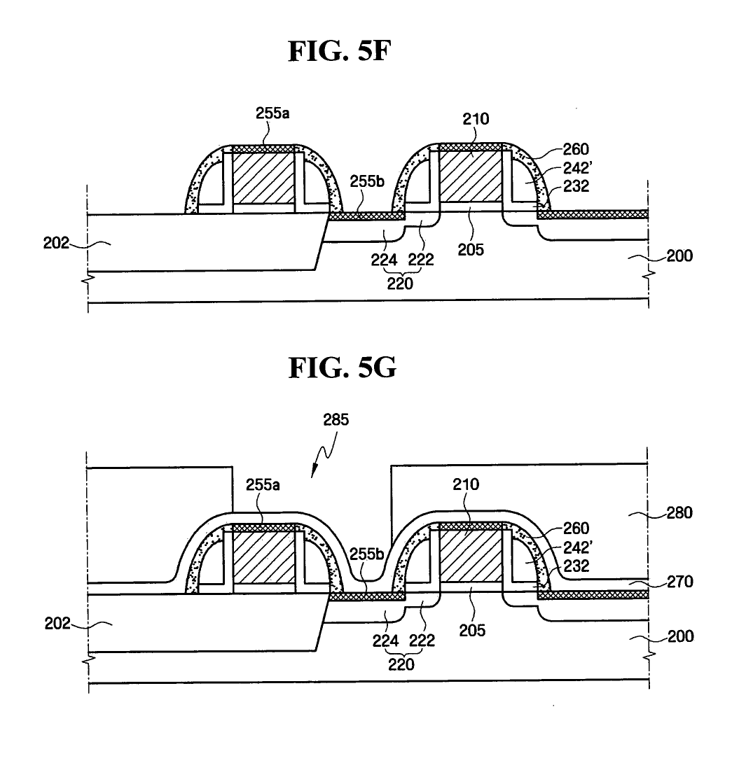

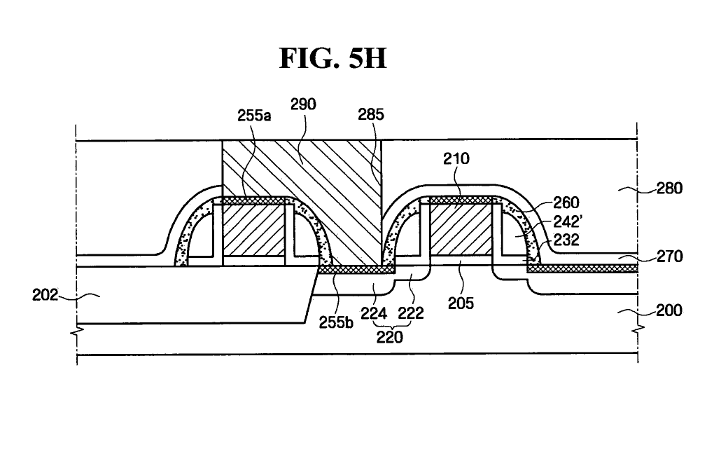

Hereinafter, with reference to FIGS. 3 and 5A to 5G, a method of fabricating a semiconductor device according to another embodiment will be described in detail. FIGS. 5A to 5G illustrate sectional views of a method of fabricating a semiconductor device according to another embodiment.

First, referring to FIGS. 3 and 5A, gate electrodes 210 may be formed on a semiconductor substrate 200 (S10). More specifically, a semiconductor substrate 200 on which an isolation region 202 for defining an active region may be formed is provided. The semiconductor substrate 200 may include, e.g., Si, Ge, SiGe, GaP, GaAs, SiC, SiGeC, InAs, and InP, or an SOI (Silicon On Insulator) substrate. Also, the isolation region 202 may be formed using, e.g., a local oxidation of silicon (LOCOS) process or a shallow trench isolation (STI) process.

Gate insulating layers 205 and gate electrodes 210 may be successively formed on a specified region of the semiconductor substrate 200. The gate insulating layers 205 and the gate electrodes 210 may be formed not only on the active region but also on the isolation region 202. The gate insulating layer 205 and the gate electrode 210 may include materials exemplified in a previous embodiment.

Then, low-density source/drain regions 222 may be formed in the semiconductor substrate 200 at the sides of the gate electrode 210 (S20). The low-density source/drain regions 222 may be formed on the active region outside of the isolation region 202. Also, n-type impurities, e.g., P or As, may be injected into an NMOS active region, while p-type impurities, e.g., B, may be injected into a PMOS active region.

Next, referring to FIGS. 3, 5B and 5C, first spacers 242 may be formed on sides of the gate electrode 210 (S30). More specifically, first and L-type spacer insulating layers 230 and 240 may be conformally formed on the surface of the semiconductor substrate 200 having the gate electrode 210. That is, the L-type spacer insulating layer and the first spacer insulating layer may be successively formed. Here, the L-type spacer insulating layer 230 may include, e.g., a silicon oxide layer, formed by, e.g., a chemical vapor deposition (CVD) or thermally oxidizing the side surfaces of the gate electrode 210. Damage to the gate electrode 210 due to etching of may be prevented by the spacer insulating layers. Also, the first spacer insulating layer 240 may include, e.g., an insulating material having etch selectivity with respect to the L-type spacer insulating layer 230, e.g., SiO₂, SiN, or SiON. Preferably, an SiO₂ layer and an SiN layer may be laminated in order on the surfaces of the semiconductor substrate 200 and the gate electrode 210.

An anisotropic etching process may be performed on the first spacer insulating layer 240. The first spacers 242 may be formed on the L-type spacer insulating layer 230 on sides of the gate electrode 210. Then, L-type spacers 232 may be formed by performing a successive etching process on the L-type spacer insulating layer 230 using the first spacers 242 as an etching mask. Accordingly, the L-type spacers 232 may conformally extend from sidewalls of the gate electrode 210 and overlie a part of the semiconductor substrate 200.

After the L-type and first spacers 232 and 242 are formed, the high-density source/drain regions 224 may be formed in the semiconductor substrate 200, i.e., in the active region, so that they may be aligned with an edge of the L-type spacers 232 (S40). Here, n-type impurities, e.g., P or As, may be injected into an NMOS active region, while p-type impurities, e.g., B, may be injected into a PMOS active region. The density of the impurities and the ion injection energy may be greater than those for forming the low-density source/drain region 222, respectively. Accordingly, the forming of the source/drain region 220 having a structure in which the low-density source/drain region 222 extends from the high-density source/drain region 224 under the lower part of the L-type spacer 232, may be completed.

Referring to FIGS. 3, 5D and 5E, the silicide layers 255a and 255b may be formed on the gate electrode 210 and the source/drain region 220, respectively (S50). More specifically, a metal layer 250 for forming the silicide layers may be conformally formed on surfaces of the semiconductor substrate 200, the gate electrodes 210, and the L-type and first spacers 242. The metal layer 250 may be formed by depositing, e.g., titanium (Ti), tungsten (W), cobalt (Co), or nickel (Ni), on the surfaces.

Then, by thermally processing the whole surface of the resultant structure, the metal material and silicon atoms may react to form silicide layers. By removing the non-reacted metal layer through, e.g., a cleaning process, the silicide layers 255a and 255b may be formed on the gate electrodes 210 and the source/drain regions 220.

Specifically, the silicide layer 255b on the source/drain region 220 may be formed only on the high-density source/drain region 224 because of the L-type and first spacers 232 and 242′. Also, the silicide layer 255b on the source/drain region 220 may be formed on the boundary between the active region 200 and the isolation region 202.

While the silicide layers 255a and 255b may be formed after the L-type and first spacers 232 and 242′ are formed on sides of the gate electrode 210, a plurality of cleaning processes, e.g., pre/post cleaning processes for the surfaces of the high-density source/drain regions 224, cleaning processes before/after the silicide layers 255a and 255b are formed, and the like, may be performed. Accordingly, a part of the L-type and first spacers 232 and 242′ on sides of the gate electrode 210 may be removed. Also, the first spacer 242′ on the L-type spacer 232 may be completely removed.

Next, as illustrated in FIGS. 3 and 5F, second spacers 260 may cover parts of the L-type spacers 232, the first spacers 242′, and end parts of the surface of the silicide layer 255b on the source/drain region 220 (S60). More specifically, the second spacers 260 may be formed by, e.g., conformally depositing a second spacer insulating layer on surfaces of the semiconductor substrate 200 having the silicide layers 255a and 255b, and then performing an anisotropic etching of the second spacer insulating layer.

The second spacer insulating layer may include, e.g., a material having an etch selectivity with respect to the etch stop layer (See 270 in FIG. 5G) formed in a subsequent process. For example, when the etch stop layer 270 includes a silicon nitride layer, the second spacers 260 may include a high-k material, e.g., silicon oxide (SiO₂), hafnium oxide (HfOₓ), zirconium oxide (ZrOₓ), hafnium oxynitride (HfOₓN_{y}), zirconium oxynitride (ZrOₓN_{y}), hafnium aluminum oxide (HfAlOₓ₎, zirconium aluminum oxide (ZrAlOₓ), hafnium silicon oxide (HfSiOₓ), zirconium silicon oxide (ZrSiOₓ), hafnium silicon oxynitride (HfSiOₓN_{y}), and zirconium silicon oxynitride (ZrSiOₓN_{y}).

The second spacers 260 may conformally extend from side walls of the silicide layer 255a on the gate electrode 210 to end parts of the surface of the silicide layer 255b on the source/drain region 220. That is, since the L-type and first spacers 232 and 242′ and sidewalls and end parts of the surface of the silicide layers 255a and 255b may be covered by the second spacer 260, loss and damage to these features may be prevented in a subsequent process.

Particularly, the second spacer 260 may cover a boundary surface between the silicide layer 255b on the source/drain region 220, and the isolation region 202, and thus damage thereof due to a subsequent etching process may be prevented.

Next, as illustrated in FIGS. 3 and 5G, an etch stop layer 270 and an interlayer insulating layer 280 may be successively formed on the semiconductor substrate 200. Then, a common contact hole 285 exposing upper parts of the silicide layers 255a and 255b on the gate electrode 210 and the source/drain region 220, respectively, may be formed (S70).

More specifically, the etch stop layer 270 may be conformally formed on surfaces of the semiconductor substrate 200, the silicide layers 255a and 255b, and the second spacers 260. The etch stop layer 270 may include, e.g., a silicon nitride layer, formed by, e.g., chemical vapor deposition (CVD).

Then, on the etch stop layer 270, the interlayer insulating layer 280 may be formed with a sufficient thickness. The interlayer insulating layer 280 may be formed as, e.g., a high-density plasma oxide layer or a CVD oxide layer. With respect to the upper surface of the interlayer insulating layer 280, a planarization process may be performed by, e.g., chemical mechanical polishing (CMP).

Thereafter, a mask pattern (not illustrated) defining a common contact hole 285 may be formed on the interlayer insulating layer 280. Then, the common contact hole 285, exposing an upper surface of the etch stop layer 270, may be formed by etching the interlayer insulating layer 280 using the mask pattern as an etching mask. The common contact hole 285 may expose the part of the etch stop layer 270 covering the silicide layers 255a and 255b on the gate electrode 210 and the source/drain region 220. Then, an over-etching may be performed with respect to the etch stop layer 270 exposed by the common contact hole 285, exposing at least part of the surface of the silicide layers 255a and 255b.

During the etching of the etch stop layer 270 through the over-etching process, the etch selectivity between the second spacer 260 and the etch stop layer 270 may be high, and thus the second spacer 260 may be maintained. Accordingly, exposure of the gate electrode 210 due to damage to the L-type spacer 232 and the first spacer 242′ may be prevented. Damage to the sidewalls and end parts of the surface of the silicide layers 255a and 255b, respectively, may also be prevented. In addition, damage to the boundary surface between the silicide layer 255b and the isolation region 202 due to the etching process may also be prevented.

Accordingly, an electrical short between the gate electrode 210 and the common contact 290 filling the common contact hole 285 may be prevented. Furthermore, an undesirable leakage current occurring at the boundary between the silicide layer 255b and the isolation region 202 may also be prevented.

As illustrated in FIGS. 3 and 5H, by filling the common contact hole 285 with a conductive material, the common contact 290 may be formed (S80). The common contact 290 may serve as, e.g., an interconnection line for electrically connecting the gate electrode 210 and the source/drain region 220 in a high-integration semiconductor device.

As described above, because the semiconductor device according to an embodiment may include spacers formed on sides of the gate electrode after the silicide layer are formed, side walls of the gate electrode and the end parts of the surface of the silicide layers may be protected. Accordingly, during the etching process for forming the contact hole, damage to the gate electrode and the silicide layers may be prevented, and thus the likelihood of an electrical short of the semiconductor device may be reduced.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A semiconductor device, comprising:
a semiconductor substrate;
a gate insulating layer on the semiconductor substrate;
a gate electrode having sidewalls, on the gate insulating layer;
first spacers on the sidewalls of the gate electrode;
a source/drain region in the semiconductor substrate, aligned with the sidewalls;
a silicide layer on the gate electrode;
a silicide layer on the source/drain region having a surface with an end part; and
second spacers covering the first spacers and the end parts of the surface of the silicide layer on the source drain region.

2. The semiconductor device as claimed in claim 1, further comprising an etch stop layer overlying at least part of the semiconductor substrate, the etch stop layer having a contact hole exposing the second spacer and at least a part of the silicide layer on the source/drain region.

3. The semiconductor device as claimed in claim 2, wherein the contact hole further exposes at least a part of the silicide layer on the gate electrode.

4. The semiconductor device as claimed in claim 1, wherein the second spacer includes a material having a high etch selectivity with respect to the etch stop layer.

5. The semiconductor device as claimed in claim 4, wherein the etch stop layer includes a silicon nitride layer.

6. The semiconductor device as claimed in claim 5, wherein the second spacer includes silicon oxide or a high dielectric constant (high-k) material.

7. The semiconductor device as claimed in claim 1, further comprising L-type spacers between the gate electrode and the first spacers, wherein the L-type spacers cover the sidewalls of the gate electrode and overlie at least a part of the semiconductor substrate.

8. The semiconductor device as claimed in claim 7, wherein the source/drain region includes a low-density source/drain region under the L-type spacer.

9. The semiconductor device as claimed in claim 1, wherein the semiconductor substrate includes an isolation region defining an active region.

10. The semiconductor device as claimed in claim 9, wherein the isolation region is in contact with a lower part of a gate electrode and the source/drain region.

11-21. (canceled)
